(19) United States
(12) Patent Application Publication
(10) Pub. No.: US 2026/0219583 A1
(43) Pub. Date: Jul. 30, 2026

(54) METHOD FOR DETERMINING AN OPTICAL PROPERTY

(71) Applicant: ASML NETHERLANDS B.V., Veldhoven (NL)

(72) Inventor: Carolus Johannes Catharina SCHOORMANS, Hooge Mierde (NL)

(73) Assignee: ASML NETHERLANDS B.V., Veldhoven (NL)

(21) Appl. No.: 19/145,560

(22) PCT Filed: Jan. 12, 2024
(86) PCT No.: PCT/EP2024/050678

§ 371 Date: Jul. 3, 2025

(30) Foreign Application Priority Data
Feb. 14, 2023 (EP) 23156496.4

(51) Int. Cl. G03F 7/00; G06F 11/30

(52) U.S. Cl. CPC G03F 7/70504; G03F 7/70266; G03F 7/70508; G03F 7/706; G03F 7/7085; G06F 11/3058

(57) ABSTRACT

A method for determining an optical property of a projection system, the method including: obtaining measured data representative of measured radiation output from the projection system; obtaining an estimated illumination profile of input radiation received by the projection system; generating, based on the estimated illumination profile, estimated data representative of estimated radiation output from the projection system; fitting the estimated data to the measured data to generate a parameter fit; and calculating, based on the parameter fit, an optical property of the projection system.

### CROSS REFERENCE TO RELATED APPLICATION

The application claims priority of EP Application Serial No. 23156496.4 which was filed on 14 February 2023, and which is incorporated herein in their entirety by reference.

### FIELD

The present invention relates to methods and apparatus for determining an optical property of a projection system. The projection system may be a projection system of a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as

‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Radiation that has been patterned by the patterning device is focused onto the substrate using a projection system. The projection system may be arranged to condition the radiation beam such that it is delivered to the patterning device with desired spatial and angular distributions. The projection system may introduce optical aberrations, which cause an image formed on the substrate to deviate from a desired image (for example a diffraction limited image of the patterning device).

It may be desirable to provide methods and apparatus for accurately determining aberrations caused by a projection system such that these aberrations can be better controlled or obviated. Furthermore, it may be desirable to provide methods and apparatus for accurately determining other properties of a projection system, for example polarisation and apodization induced by the projection system. Such properties can also cause the image formed on the substrate to deviate from a desired image.

### SUMMARY

According to a first aspect there is provided a method for determining an optical property of a projection system. The method comprises: obtaining measured data representative of measured radiation output from the projection system; obtaining an estimated illumination profile of input radiation received by the projection system; generating, based on the estimated illumination pupil and/or profile, estimated data representative of estimated radiation output from the projection system; fitting the estimated data to the measured data to generate a parameter fit; and calculating, based on the parameter fit, an optical property of the projection system.

The radiation output from the projection system has an illumination profile which differs from the input illumination profile. At least some of the difference can be due to optical properties of the projection system which, in turn, induce changes to the radiation. The changes can include, for example, phase shifts (e.g. due to aberrations), changes in intensity (e.g. due to apodization) and/or changes in polarization. It is beneficial to accurately determine the optical properties of the projection system so that such changes can be accounted for, for example in any imaging process which uses the projection system. The method enables the accurate determination of one or more optical properties of a projection system with reduced processing requirements. As such, the determination can be done more quickly and hence can be performed regularly without requiring significant apparatus downtime. Furthermore, the method can be performed without specialist apparatus (e.g. high power on-board processing) which can be required for some other methods of determining the optical property. Therefore, the method can be performed at the user side and/or during the typical lifetime of the apparatus. This may be beneficial compared to other methods which may only be performed upon initial manufacture, testing and/or calibration of a projection system. The method may be computer implemented. The measured data may be representative of measured radiation output from the projection system during a shearing interferometry process.

The measured data may represent at least one component of the measured output radiation, wherein the component is selected from the set of: a phase component, an amplitude component, and an offset component. The estimated data may represent a corresponding at least one component of the estimated output radiation. That is, if the measured data includes a phase component, the estimated data may also include a phase component. It has been found that an accurate determination of an optical property can be performed using fewer than all components of the measured data or simulated data, which requires relatively low processing power.

The component of the measured data and the corresponding component of the estimated data may each comprise the phase component. The phase components are at least partially representative of aberrations in the lithographic apparatus, for example aberrations due to optical components in the lithographic apparatus. The phase components may also represent other optical properties such as apodization and polarization, changes of which may be induced by optical components. Therefore, optical properties such as these can be determined using the phase components of the estimated and measured data.

Obtaining the estimated illumination profile may comprise obtaining simulated data representative of simulated radiation output from the projection system, fitting the measured data to the simulated data to generate a profile fit; and generating, based on the profile fit, the estimated illumination profile. The simulated data may comprise multiple sets of simulated data. Each set of the multiple sets may be based on the input, to the projection system, of radiation with a predetermined illumination profile of a set of predetermined illumination profiles. The estimated illumination profile may comprise a weighted combination of the set of predetermined illumination profiles. The simulated data may be pre-calculated. The use of pre-calculated simulated data enables fast implementation of simulated data, such that determinations can be performed relatively quickly and with relatively low processing requirements. Alternatively, the simulated data can be directly simulated when required. The simulated data can be generated based on ray tracing through the projection system for each of the predetermined illumination profiles. Alternative methods of generating simulated data are possible, for example using an optical model of the projection system, for example representing the optical (e.g. diffraction) physics occurring in the projection system.

Each of the predetermined illumination profiles may be at least partially defined by an angular distribution, an apodization and/or a polarization of the input radiation. Beneficially, real physical effects such as aberrations, apodization and polarization induced by optical elements of the projection system can be determined in this way.

The measured data may represent at least one component of the measured output radiation. The at least one component may be selected from the set of: a phase component, an amplitude component, and an offset component. The simulated data may represent a corresponding at least one component of the estimated output radiation. That is, if the measured data includes an offset component, the simulated data may also include an offset component. It has been found that an accurate determination of an optical property can be performed using fewer than all components of the measured data or simulated data, which requires relatively low processing power.

The component of the measured data and the corresponding component of the simulated data may each comprise the offset component. The offset components of the measured data and simulated data are independent of aberrations in the lithographic apparatus. As such, fitting using the amplitude or offset components can provide a determination of an optical property of the projection system relatively quickly and with relatively low processing requirements.

The measured data, the simulated data and/or the estimated data may comprise images. The images may be visually represented. The images may comprise data points (e.g. pixels) having a relative spatial dependence.

The simulated data may be calculated by obtaining a theoretical model of the projection system and propagating each of the set of predetermined illumination profiles using said theoretical model. The theoretical model may define or approximate the optical properties of the projection system. The theoretical model may provide an approximation of the diffraction of radiation propagating through the projection system. Said calculation can be performed ahead of time, i.e. pre-calculation. Alternatively, the simulated data can be calculated on demand.

Fitting may comprise fitting basis functions to the data. The basis functions may be Zernike polynomials. Alternatively, other basis functions may be used, for example Tatian Zernike polynomials.

The optical property may comprise one or more aberrations induced by the projection system. The optical property may additionally or alternatively comprise apodization of the projection system. The optical property may additionally or alternatively comprise a polarization induced by the projection system. Such optical properties may be affected by one or more of multiple optical elements in the projection system. Beneficially, real physical effects such as aberrations, apodization and polarization induced by the projection system can be determined using this method.

Each of the predetermined illumination profiles may be represented using polynomials. Polynomials up to a finite order may be used, for example to beneficially reduce processing requirements and hence increase the speed of the method. Any number of polynomial functions may be used, for example two three or ten. Three orders may provide a beneficial compromise between speed and accuracy of the method.

The method may further comprise calculating an adjustment based on the determined optical property. The adjustment may comprise a calibration of the projection system or a component external to the projection system. One or more components may be adjusted. The adjustment may comprise or further comprise a real-time control operation, for example of the projection system or a component external to the projection system. One or more components may be controlled.

Beneficially, one can use the methods herein to make an adjustment to the projection system, therefore improving the performance of the projection system or an associated process. The process may be, for example, a future exposure performed by imaging using the projection system. As described above, the methods herein can be performed without specialist apparatus (e.g. ray tracing means, high power processing) which can be required for some other methods. Such other methods may be performed once for a type of lithographic apparatus, and the data determined therefrom used to calculate adjustments to apply to all apparatus of that type. The methods herein, on the other hand, can be performed at the user side and/or during the typical lifetime of the lithographic apparatus, enabling adjustments to be calculated which are specific to the particular lithographic apparatus. This is particularly beneficial for apodization which can depend on each individual lens used in a specific lithographic apparatus, and therefore is difficult to generalise for apparatus of the same type. It follows that an adjustment calculated according to the methods herein may provide more accurate adjustments to optimize for apodization effects for a specific lithographic apparatus.

The method may further comprise providing an instruction to a means for adjusting the projection system or external component to apply said adjustment. The means for adjusting the projection system may be, for example, a controller. The controller may be configured to control a position, tilt, or other characteristic of an element associated with the projection system. For example, the element may be an optical element of the projection system, or a support structure positioning an item in an object plane or image plane of the projection system. The instruction may therefore comprise an instruction to change the position, tilt, or other characteristic of said element.

The method may further comprise providing an indication that the projection system or an element thereof needs replacing. Replacement of the projection system or an associated element may obviate imaging problems associated with the determined optical property. For example, it may be determined that higher than acceptable aberrations are induced by the projection system, and that adjustments are unable to adequately correct the aberration. In this case, an indication to replace an optical element which may be contributing to the determined aberration may be provided, such that the aberration is reduced or obviated. Alternative to replacement, the indication may indicate that the projection system or an element thereof needs cleaning.

According to a second aspect of the invention there is provided a method for determining an optical property of a projection system, the method comprising: obtaining a measured illumination profile of input radiation received by the projection system; fitting the measured illumination profile to a set of predetermined illumination profiles to generate a parameter fit; and calculating, based on the parameter fit, an optical property of the projection system. Obtaining a measured illumination profile may comprise: illuminating a pinhole in an object plane of the projection system and receiving radiation output from the projection system while scanning said illuminated pinhole within the object plane.

Each of the predetermined illumination profiles may be at least partially defined by an intensity, an apodization and/or a polarization of the input radiation. Beneficially, real physical effects such as aberrations, apodization and polarization induced by optical elements of the projection system can be determined in this way.

According to a third aspect of the invention there is provided a method of determining an estimated illumination profile of a projection system, comprising: obtaining measured data representative of measured radiation output from the projection system; obtaining simulated data representative of simulated radiation output from the projection system; fitting the measured data to the simulated data to generate a profile fit; and generating, based on the profile fit, the estimated illumination profile, wherein the estimated illumination profile comprises a weighted combination of the set of predetermined illumination profiles. The simulated data may comprise multiple sets of simulated data. Each set of the multiple sets may be based on the input, to the projection system, of radiation with a predetermined illumination profile of a set of predetermined illumination profiles. While a desired illumination pupil and/or profile may be selected, the actual illumination pupil and/or profile may be different to that desired. It is beneficial to accurately determine an estimated illumination pupil and/or profile of the projection system such that an imaging process which use the projection system can be optimized. The method enables the accurate determination of the estimated illumination pupil and/or profile with reduced processing requirements. Furthermore, the method can be performed without specialist apparatus (e.g. high power on-board processing) which can be required for some other methods of determining the illumination profile. Therefore, the method can be performed at the user side and/or during the typical lifetime of the apparatus. This may be beneficial compared to other methods which may only be performed upon initial manufacture, testing and/or calibration of a projection system. The method may be computer implemented. The measured data may be representative of measured radiation output from the projection system during a shearing interferometry process.

According to a fourth aspect of the invention there is provided a method for determining an optical property of a projection system, the method comprising: obtaining measured data representative of measured radiation output from the projection system; obtaining simulated data representative of simulated radiation output from the projection system; fitting the measured data to the simulated data to generate a parameter fit; and calculating, based on the parameter fit, an optical property of the projection system.

The radiation output from the projection system has an illumination profile which differs from the input illumination pupil and/or profile. The difference can be due to optical properties of the projection system which, in turn, induce changes to the radiation. The changes can include, for example, phase shifts (e.g. due to aberrations), changes in intensity (e.g. due to apodization) and/or changes in polarization. It is beneficial to accurately determine the optical properties of the projection system so that such changes can be accounted for, for example in any imaging process which uses the projection system. The method enables the accurate determination of one or more optical properties of a projection system with reduced processing requirements. As such, the determination can be done more quickly and hence can be performed regularly without requiring significant apparatus downtime. Furthermore, the method can be performed without specialist apparatus (e.g. high power on-board processing) which can be required for some other methods of determining the optical property. Therefore, the method can be performed at the user side and/or during the typical lifetime of the apparatus. This may be beneficial compared to other methods which may only be performed upon initial manufacture, testing and/or calibration of a lithographic apparatus. The method may be computer implemented. The measured data may be representative of measured radiation output from the projection system during a shearing interferometry process.

According to a fifth aspect of the invention there is provided a computer-readable medium comprising instructions which, when executed by a computer, cause the computer to perform the method of any of the first, second, third, fourth or fifth aspects.

According to a sixth aspect of the invention there is provided a measurement system comprising a projection system and a processor configured to perform the method of any of the first, second, third, fourth or fifth aspects.

The measurement system may further comprise a first support configured to hold a first measurement patterning device in an object plane of the projection system. The measurement system may further comprise a second support configured to hold a second measurement patterning device in an image plane of the projection system. The measurement system may further comprise a positioning system configured to scan at least one of the first and second supports with respect to the other of the first and second supports. The measurement system may further comprise a sensor configured to generate the measured data.

The measurement system may further comprise a controller operable to apply an adjustment to the projection system or a component external to the projection system. Additionally or alternatively, the controller may be operable to provide an indication that the projection system or an element thereof needs replacing or cleaning.

According to a seventh aspect of the invention there is provided a lithographic apparatus comprising the measurement system of the sixth aspect. At present, accuracy requirements for lithographic processes are high. Better definition or optimization of the optical properties of the projection system, or the illumination profile received by the projection system, can help achieve such high accuracy requirements.

The lithographic apparatus may further comprise a controller operable to apply an adjustment to the lithographic apparatus. The adjustment may be to the projection system or an element thereof.

The lithographic apparatus may further comprise a display screen configured to display an indication. The indication may be an indication that the projection system or a component thereof needs replacing or cleaning.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a measurement system which may be used in combination with methods described herein;

FIG. 3 illustrates a method for determining an optical property of a projection system;

FIG. 4 illustrates a method for determining an estimated illumination profile of a projection system;

FIG. 5 illustrates an alternative method for determining an optical property of a projection system

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

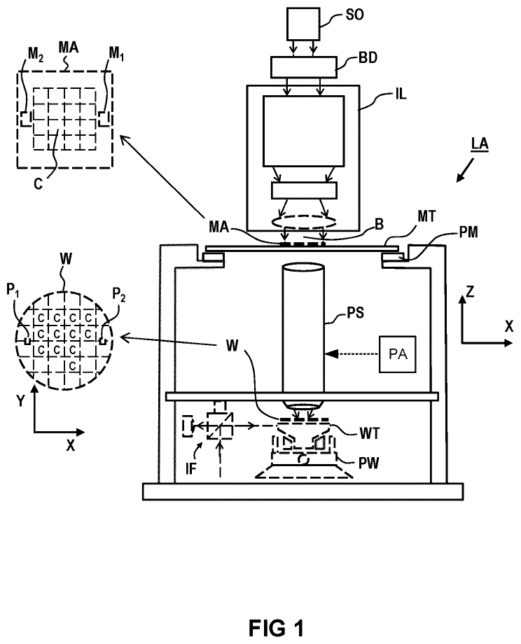

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W. The plane in which the mask MA may be supported (i.e. the plane of the mask table MT) may be referred to as the mask level. The plane in which the substrate W may be supported (i.e. the plane of the substrate support WT) may be referred to as the substrate level. The mask level and substrate level may be considered an object plane and an image plane of the projection system, respectively. The mask level and substrate level are defined in reference to the projection system and are present regardless of whether a support or a structure is positioned at the mask level or substrate level.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA. The spatial and angular intensity distribution of the radiation beam B may be referred to as an illumination pupil. Other characteristics of the radiation beam B may also be controlled, for example the polarization of the radiation beam B. The specific characteristics of the radiation beam B may be referred to as the illumination profile of the radiation beam B. The illumination profile may be selected based on, for example, properties of the projection system PS, patterning device MA and/or substrate W. The lithographic exposure may be optimized for accuracy and/or duration. The illumination pupil and/or profile may be selected to optimize a lithographic exposure.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may also be of a type having two or more substrate supports WT (also named “dual stage” or “multiple stage”). In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor. The sensor may be arranged to measure a property of the projection system PS or a property of the radiation beam B. The measurement stage may hold multiple sensors. The measurement stage may move beneath the projection system PS when the substrate support WT is away from the projection system PS. The plane of the measurement stage may be referred to as a measurement level, regardless of whether one or more sensors are located therein. The measurement level is located close to the image plane of the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

The projection system PS may induce optical aberrations and illumination pupil and/or profile errors. As such, while a desired illumination pupil and/or profile may be selected, the actual illumination pupil and/or profile received at the substrate W may be different to that desired. As a result, the projection system PS can affect the quality and characteristics of the image projected by the projection system PS. Errors and aberrations can affect the patterning accuracy, critical dimensions and overlay of a lithographic exposure.

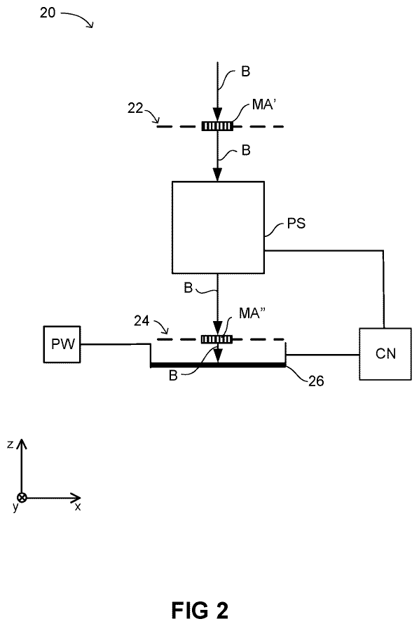

FIG. 2 is a schematic illustration of a measurement system 20 which may be used to determine an optical property of a projection system PS, for example aberrations which are caused by the projection system PS. The measurement system 20 may form part of a lithographic apparatus. For example, the projection system PS shown in FIG. 2 may be the projection system PS of the lithographic apparatus shown in FIG. 1. The measurement system 20 comprises a first measurement patterning device MA′ which can be positioned at the mask level 22, for example supported by a mask support such as the mask support MT depicted in FIG. 1. The mask level 22 is an object plane 22 of the projection system PS. The measurement system 20 also comprises a second measurement patterning device MA″ which can be positioned at the substrate level 24, for example supported by a substrate support such as the substrate support WT depicted in FIG. 1. The substrate level 24 is an image plane 24 of the projection system PS. The measurement patterning devices MA′, MA″ comprise a plurality of patterned regions, for example in the form of a reflective or transmissive diffraction grating. Radiation incident on the measurement patterning devices MA′, MA″ is therefore at least partially refracted and/or diffracted due to interaction with the measurement patterning devices MA′, MA″.

The measurement system 20 also comprises a sensor 26 positioned to detect radiation which has been transmitted through (or refracted or diffracted by) the second measurement patterning device MA″. The sensor 26 may be positioned in a plane which is conjugate to a pupil plane of the projection system PS. The sensor 26 is configured to detect the spatial intensity profile of radiation which is incident on the sensor 26. The sensor 26 may, for example, comprise an array of individual detector elements or sensing elements. For example, the sensor 26 may comprise an active pixel sensor such as, for example, a CMOS (complementary metal-oxide-semiconductor) sensor array. Alternatively, the sensor 26 may comprise a CCD (charge-coupled device) sensor array.

In use, a radiation beam B is provided to the measurement system 20. The radiation beam B may be, for example, provided by an illumination source such as the illumination source IL of the lithographic apparatus LA in FIG. 1. The propagation of the radiation beam B through the measurement system 20 is shown with arrows in FIG. 2. In the notional Cartesian coordinate system used for illustrative purposes, the radiation beam B travels generally in the negative z direction through the measurement system 20. It should be understood, however, that other arrangements of measurement systems are possible which perform functionally similar to that described herein. In such other measurement systems, the radiation beam may travel in different directions and may, for example, have its path diverted by optical elements such as mirrors. The radiation beam B provided to the measurement system may be modified for use in a measurement process using the measurement system 20. For example, the radiation beam B may be diffused.

The radiation beam B is directed to the first measurement patterning device MA′. The radiation beam B interacts with the first measurement patterning device MA′ before being received by the projection system PS as input radiation. The radiation B is projected, by the projection system PS, such that an image of the first measurement patterning device MA′ in the object plane 22 is formed at the image plane 24. During a measurement process, the second measurement patterning device MA″ is positioned to be generally co-located with the formed image of the first measurement patterning device MA′. The radiation beam B interacts with the second measurement patterning device MA″ before being received by the sensor 26. The radiation received by the sensor 26 contains an interference pattern due to the interaction of the radiation beam B with the measurement patterning devices MA′, MA″.

The measurement system 20 also comprises a positioning system PW. The positioning system moves the second measurement patterning device MA″ within the image plane 24 (for example, in the notional x-y plane). The positioning system PW may move the second measurement patterning device MA″ itself, or may move a support which holds the second measurement patterning device MA″, and movement of or scanning of the second measurement patterning device MA″ may be considered to include cither arrangement. Due to the movement, the second measurement patterning device MA″ scans with respect to the first measurement patterning device MA′, albeit in a conjugate plane. As such, the second measurement patterning device MA″ scans with respect to the image of the first measurement patterning device MA′ projected onto the image plane 24. The second patterning device MA″, and/or a support which holds the second measurement patterning device MA″, is mechanically coupled to the sensor 26 such that the sensor is also scanned with respect to the first measurement patterning device MA′. The mechanical coupling is not shown in FIG. 2, but may comprise, for example, a physical connection between the sensor 26 and a support table which holds the second measurement patterning device MA″.

In other arrangements, the sensor 26 need not be mechanically coupled to the second measurement patterning device MA″ and/or its support. In such arrangements, the second measurement patterning device MA″ (or its support) can be moved without movement of the sensor. Alternatively, the positioning system PW may move the first measurement patterning device MA′ (or its support) such that the first measurement patterning device MA′ scans with respect the second measurement patterning device MA″. In any arrangement, the positioning system PW may be considered to provide relative scanning between the first and second measurement patterning devices MA′, MA″.

The movement (scanning) may be performed in steps. That is, rather than a continuous movement of the second measurement patterning device MA″, the device MA″ is moved in discrete steps. The size of the steps may be selected based on the pitch of the diffraction gratings of the measurement patterning devices MA′, MA″. The scanning may also be performed in more than one direction. For example, the measurement patterning devices MA′, MA″ may be moved relative to one another in the x-direction and subsequently in the y-direction. Alternatively, the measurement patterning devices MA′, MA″ may be moved relative to one another in the y-direction and subsequently in the x-direction. Alternatively, the measurement patterning devices MA′, MA″ may be moved relative to one another in the x-direction and γ-direction simultaneously. By scanning the first or second measurement patterning devices MA′, MA″ with respect to each other, a shearing interferometer is formed. The sensor 26 is positioned to measure the interference pattern formed by radiation travelling through the first and second patterning devices MA′, MA″ at a particular relative position to one another. The generation of data in this manner may be considered to be generated during a shearing interferometry process. Measurements which are made at different scanning positions may be analysed in order to derive information about the radiation in each relative scanning position.

The sensor 26 outputs data representative of the radiation upon the sensor 26 at a particular scanning position. Said output data can be visually represented as an image. By taking a measurement using the sensor 26 in multiple scanning positions, a set of data (or a set of images) can be obtained. Each image represents the spatial intensity profile of radiation incident at the sensor 26 at a respective scanning position. The intensity of radiation at each position on the sensor 26, for example at each pixel, will vary as the scanning takes place (i.e. varies with each scanning position). The variation is typically periodic in nature. From the varying signal measured by the sensor 26, multiple types of information can be extracted from the data obtained by the sensor 26, for example by decomposing the varying signal. In particular, an offset, an amplitude and a phase difference (also referred to as a phase shift) can be extracted. In order to extract said information, the varying signal can be decomposed using a sinusoidal function. Typically, the longest sinusoidal period which matches the varying signal is used. However, higher orders and/or non-sinusoidal variations can also be used for decomposition.

The offset is a measure of the average intensity of radiation, for example averaged over an integer number of periods of sinusoidal variation. The amplitude is a measure of the difference between the offset and the maximum (and/or minimum) intensity measured. The phase difference is a measure of the phase shift of the sinusoidal function fitted to the periodic signal. For a given incoming beam direction, each diffraction order of the radiation which has been diffracted by the first measurement patterning device MA′ experiences a phase shift corresponding to the light trajectory of the diffraction order through the projection system PS. The phase shift is therefore induced by the projection system PS. Each diffraction order is subsequently diffracted by the second measurement patterning device MA″, and may be diffracted in a different direction onto a different light trajectory. Due to coherent and incoherent interference of the diffraction orders based on their trajectory, the signal output by the sensor 26 captures the phase shift information. The data described herein that represents a phase difference is also referred to as phase data, or a phase component of the data. The offset may also be referred to as a direct current (DC). The amplitude may also be referred to as an alternating current (AC). The term contrast may also be used in reference to twice the amplitude (i.e. 2×amplitude or 2×AC).

The extracted offset data represents the offset in each position on the sensor 26 and can be visually represented as an image (for example, with the ‘intensity’ in each position quantifying the magnitude of the offset), referred to as an offset map. Similarly, the extracted amplitude data represents the amplitude in each position on the sensor 26 and can be visually represented as an image (e.g., with the ‘intensity’ in each position quantifying the magnitude of the amplitude), referred to as an amplitude map. Again similarly, the extracted phase data represents the phase in each position on the sensor 26 and can be visually represented as an image (e.g., with the ‘intensity’ in each position quantifying the magnitude of the phase difference), referred to as a phase map.

In general, the projection system PS has an optical transfer function which may be non-uniform, which can affect the image projected by the projection system PS. The projection system PS can induce a phase shift (e.g. due to aberrations), changes in intensity (e.g. due to apodization (transmission) of radiation travelling therethrough) and changes in polarization. The magnitude of these effects and their properties (e.g. type of aberration) may also depend on the polarization of the radiation. Analysis of one or more of the offset, amplitude and phase data can yield information about the aberrations, polarization and apodization induced by the projection system PS. Other components of the measurement system 20, for example the sensor 26, may also induce aberrations (e.g. a phase shift), changes in polarization and changes in intensity. As such, it can be beneficial to calibrate for such aberrations and changes to accurately identify the properties of the projection system PS. Most changes induced by the sensor 26 will typically have a “fingerprint” which differs from the projection system and are thus distinguishable. Therefore, any contribution induced by the sensor 26 can be removed from the data.

The aberrations, polarization and apodization of (or induced by) the projection system PS can be referred to simply as optical properties of the projection system PS. Generally, it is convenient to have an accurate understanding of the optical properties of a projection system PS. By accurately knowing the optical properties of the projection system PS, the expected image projected by the projection system PS can be predicted with more accuracy. By accurately knowing the optical properties of the projection system PS, adjustments to the projection system PS can be made so as to optimize the image formed. A projection system PS typically comprises a plurality of optical elements. An adjustment can be made to one or more of these optical elements based on the optical properties of the projection system PS. Such an adjustment can correct for the optical properties of the projection system PS, for example it may correct for aberrations induced by the projection system PS. Alternatively, an indication may be provided that an optical element should be replaced, cleaned or otherwise processed. The indication may be to a user, for example it may be displayed on a display screen associated with the projection system PS, measurement system 20, or external apparatus.

FIG. 2 further depicts a controller CN. The controller CN is operable to apply an adjustment to the projection system PS, for example an adjustment to one or more of the optical elements of the projection system PS. The controller CN, or an adjusting means to which the controller CN sends an instruction, may be operable to do any combination of the following: displace one or more optical elements; tilt one or more optical elements; and/or deform one or more optical elements. Displacement of optical elements may be in any direction (x, y, z or a combination thereof). Tilting of optical elements is typically out of a plane perpendicular to the optical axis, by rotating about axes in the x or y directions although a rotation about the z-axis may be used for non-rotationally symmetric optical elements. Deformation of an optical element may be performed for example by using actuators to exert force on sides of the optical element and/or by using heating elements to heat selected regions of the optical element.

The controller CN may additionally or alternatively be arranged to apply an adjustment to components external to the projection system PS. For example, the controller CN may be operable to adjust the support structure MT and/or the substrate table WT of the lithographic apparatus LA of FIG. 1 so as to correct for aberrations which are caused by placement errors. The adjustment, whether an adjustment of the projection system or a component external to the projection system, may be in the form of a calibration or a real-time adjustment. A calibration may be performed prior to the use of the projection system for an intended purpose, for example a series of lithographic exposures. A calibration may be performed periodically, for example once a day or week. A real-time adjustment may be performed more regularly, for example once an hour or minute. The real-time adjustment may be referred to as a real-time control operation as it can control an operation while it is occurring. As described in more detail below, the processes described herein are computationally less intensive than other methods of determining adjustments, and as such may be well suited to real-time adjustment.

The controller CN may also comprise, or be in communication with, a processor (not shown) which is configured to determine such an adjustment, for example based on one or more optical properties of the projection system PS. Methods of determining an optical property of the projection system PS are described in more detail below.

The controller CN may additionally or alternatively be configured to provide an indication that an optical element should be replaced, cleaned or otherwise processed. The controller CN may be in communication with a display screen for displaying said indication.

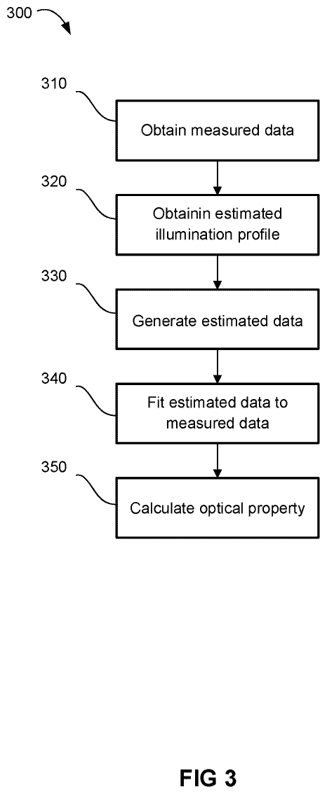

FIG. 3 illustrates a method 300 for determining an optical property of a projection system, for example the projection system PS of FIG. 2.

In a first step 310, measured data representing radiation output from the projection system is obtained. The measured data is associated with (for example, obtained from) empirical measurements of radiation which has travelled through a real projection system. That is, the measured data is associated with actual (measured) radiation output from the projection system when the projection system receives, as an input, actual input radiation. The measured data may be generated using the measurement system 20 described above with reference to FIG. 2. For example, the input radiation is the radiation beam B, and the measured data can comprise the signal output by the sensor 26, or data extracted therefrom (e.g. offset, amplitude and/or phase data). The measured data can be measured as part of the method 300 for determining an optical property of the projection system, for example as a real-time measurement prior to or simultaneously with other steps of the method 300. Alternatively, the measured data may be obtained from previously measured data. For example, the measured data may have been generated previously from a historical measurement process and stored in a storage device. In this scenario, obtaining the measured data can include receiving the measured data from said storage.

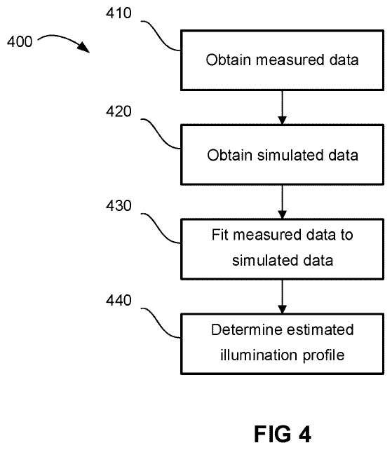

In a second step 320, an estimated illumination profile is obtained. The estimated illumination profile is an estimate of the characteristics of the radiation beam (e.g. spatial and angular intensity distribution and/or polarization) received by the projection system. It should be understood that, while an illumination system which provides the radiation to the projection system may be controlled to provide radiation with a desired illumination profile, the actual illumination profile provided can differ from the desired illumination profile. Methods for obtaining the estimated illumination profile are described in more detail below and with reference to FIG. 4.

In a third step 330, estimated data is generated. The estimated data is calculated based upon the estimated illumination profile obtained in the second step 320. The estimated data represents the estimated radiation which would be output from the projection system when the projection system receives, as an input, radiation with the estimated illumination profile. The estimated data can be generated using general optical principles dictating the propagation of radiation, based on the currently known optical properties of the projection system (for example, the known size, refractive indices etc. of the various optical components therein). The estimated data can be in the form of an estimated signal which would be output by a sensor, or data extracted therefrom (e.g. offset, amplitude and/or phase data).

In a fourth step, 340, the estimated data is fitted to the measured data. Fitting can include fitting a set of basis functions to the measured data. A particularly convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be obtained from a measured scalar map by calculating the inner product of the measured scalar map with each Zernike polynomial in turn and dividing this by the square of the norm of that Zernike polynomial. It will be appreciated that other sets of basis functions may be used. For example, some embodiments may use Tatian Zernike polynomials, for example for obscured aperture systems.

The estimated data can be fitted directly to the measured maps. Alternatively, the data can be compressed, for example by representing each dataset in terms of Zernike polynomials. In the compressed format, the fitting can then be performed by comparison of the Zernike coefficients of the estimated data and the Zernike coefficients of the measured data. Using the compressed format has the benefit that storage space is reduced and processing speed is increased.

The output of fitting the estimated data to the measured data is a parameter fit. The parameter fit may comprise, for example, a set of Zernike coefficients which quantify the fit. A finite number of coefficients may be determined, for example Zernike coefficients with a Noll index up to five. A Noll index of five is used for illustrative purposes only, and any number of coefficients may be used, for example up to a Noll index of 3, 10, or any other number.

In a fifth step 350, an optical property of the projection system is determined based on the parameter fit. For example, the Zernike coefficients calculated based on the fit may be used to determine one or more aberrations induced by the projection system. The phase component of the measured data can be referred to as a wavefront aberration map, which represents the distortions of the wavefront of light approaching a point in an image plane of the projection system PS from a spherical wavefront (as a function of position in the pupil plane or, alternatively, the angle at which radiation approaches the image plane of the projection system PS). This wavefront aberration map W(x, y) may be expressed as a linear combination of Zernike polynomials:

$$W ( x , y ) = {\sum }_{n} {Z}_{n} \cdot {z}_{n} ( x , y ) \qquad ( 1 )$$

where x and y are coordinates in the pupil plane, zₙ(x,y) is the n^{th} Zernike polynomial and Zₙ is a Zernike coefficient having a Noll index of n. The wavefront aberration map may then be characterized by the set of coefficients Zₙ in such an expansion. Different Zernike coefficients may provide information about different forms of aberration which are caused by the projection system PS.

The first Zernike coefficient Z₁ relates to a mean value (which may be referred to as a piston) of a measured wavefront. The first Zernike coefficient may be irrelevant to the performance of the projection system PS. The second Zernike coefficient Z₂ relates to the tilt of a measured wavefront in the x-direction. The tilt of a wavefront in the x-direction is equivalent to a placement of a projected image in the x-direction. The third Zernike coefficient Z₃ relates to the tilt of a measured wavefront in the y-direction. The tilt of a wavefront in the y-direction is equivalent to a placement of a projected image in the y-direction. The fourth Zernike coefficient Z₄ relates to a defocus of a measured wavefront. The fourth Zernike coefficient is equivalent to a placement of a projected image in the z-direction. Higher order Zernike coefficients relate to other forms of aberration which are caused by the projection system (e.g. astigmatism, coma, spherical aberrations and other effects).

Throughout this description, the term “aberrations” should be intended to include all forms of deviation of a wavefront from a perfect spherical wavefront. That is, the term “aberrations” may relate to the placement of an image (e.g. the second, third and fourth Zernike coefficients) and/or to higher order aberrations such as those which relate to Zernike coefficients having a Noll index of five or more.

The inventor has realised that determining optical properties of the projection system by fitting the measured data in combination with estimated data provides a more accurate determination of the optical properties compared to fitting the measured data alone, or fitting the measured data based on an assumed (e.g. desired) illumination profile. Furthermore, the fitting can be less computationally intensive, for example because can be based upon some pre-calculated information i.e. the estimated data. As a result, the fitting can take into consideration more coefficients and hence account for higher order effects. Alternatively, the process may be implemented more quickly and with lower processing requirements. The quicker process, with reduced hardware requirements, may therefore be implemented in real-time more easily.

The inventor has further realised that the process can be improved further by use of selected components of the data, for example the offset data, amplitude data or phase data. Particular components are particularly suited for certain operations, and therefore use of isolated components may simplify the operations considerably.

In the example above, wherein fitting is performed to determine aberrations induced by the projection system, the phase component of the estimated data and the phase component of the measured data may be used in the fitting process, for example because aberrations are well represented by the phase of the wavefront. The phase component of the estimated data may be fit using Zernikes to provide a set of estimated Zernike coefficients. This set of estimated Zernike coefficients can be used to fit Zernikes to the measured data. Because a set of estimated Zernike coefficients are provided as a starting point for the fitting process, fitting basis functions to the measured data is less computationally intensive. Therefore, a more accurate determination of the actual Zernike coefficients which fit the measured data can be obtained. Consequently, a more accurate determination of the aberrations can be achieved. In other example implementations, other optical properties such as apodization and polarization can also be determined based on the fit.

While the steps of the method for determining an optical property of the projection system are denoted first, second, third etc., this does not imply a particular order. While some steps should be performed sequentially (for example, the first step 310 of obtaining measured data must be performed prior to the fourth step 340 of fitting to the measured data), other steps may be performed in any order. In particular, obtaining measured data 310 and obtaining the estimated illumination profile 320 may be performed in any order including simultaneously.

FIG. 4 illustrates a method for determining an estimated illumination profile of a projection system. The estimated illumination profile may be, for example, the estimated illumination profile used in the method 300 described above with reference to FIG. 3.

In a first step 410, measured data is obtained. The obtaining of measured data is described in detail above with reference to FIGS. 2 and 3, and will not be described further here.

In a second step 420, simulated data is obtained. The simulated data represents simulated radiation that would be output from the projection system given a particular input radiation. The simulated data comprises multiple sets of simulated data. Each set may be based upon the input, to the projection system, of radiation with a predetermined illumination profile of a set of predetermined illumination profiles.

The predetermined illumination profiles may be defined in terms of their illumination pupil, apodization and/or polarization. Any illumination profile can be represented, or at least approximated, by a combination of polynomial functions. For example, the spatial and/or angular intensity distribution defining the illumination pupil may be represented by a two-dimensional polynomial across the field of the radiation beam. A set of polynomial functions which describe illumination profiles may be, for example, the set: 1, x, y, . . . , x³, x²y, xy², y³, . . . . Any number of polynomial functions may be used, for example two, three or ten. A smaller number of orders may speed up the method, whereas an increased number may increase the accuracy of the estimated illumination profile determined. Three orders may provide a beneficial compromise between speed and accuracy. Each predetermined illumination profile is represented by one of, or a combination of, the set of polynomial functions. The set may contain predetermined illumination profiles which correspond to desired illumination profiles and/or include deviations from desired illumination profiles which occur due to common aberrations.

The set of predetermined illumination profiles may also comprise any number of illumination profiles. Similar to with the number of polynomial functions, an increased number of predetermined illumination profiles may increase the accuracy of the estimated illumination profile determined, whereas a lower number of predetermined illumination profiles may increase the speed of calculations. A set of ten may provide a beneficial compromise between speed and accuracy, although any number can be used, for example two, ten, fifteen or twenty-one.

The propagation of radiation with each predetermined illumination profile through the projection system is simulated to generate the simulated data. Such a simulation may be performed using known optical principles dictating the propagation of radiation. The propagation may be based upon a theoretical model of the projection system, for example accounting for the currently known optical properties of the projection system and the optical components therein. For example, the theoretical model may include the known sizes, focal lengths and refractive indices of the optical components in the projection system. Alternatively, the simulated data may be generated using a ray-tracing process. The simulated data can be in the form of a simulated signal output by a sensor, or data extracted therefrom (e.g. offset, amplitude and/or phase data).

The simulated data can be generated in real-time as part of the method of determining the estimated illumination pupil and/or profile 400. Alternatively, the simulated data may be pre-calculated and obtained, for example from storage, when required. The simulated data may be simulated based on the specific projection system for which the estimated illumination pupil and/or profile is being determined, or for a general projection system of the same type.

In a third step 430, the measured data is fitted to the simulated data to generate a profile fit. Fitting can include fitting a set of basis functions, for example the Zernike polynomials as described above with reference to the fourth step 340 of the method 300 of FIG. 3. The discussion of fitting and Zernikes above can be applied equally to the third step 430 of this method 400.

In a fourth step 440, the profile fit is used to determine an estimated illumination profile. The estimated illumination profile is represented by a weighted combination of the set of predetermined illumination pupil and/or profile. Whereas in other methods, the assumed illumination profile may be based solely on the desired illumination profile believed to be provided by the illumination system, in this method a more accurate estimation of the illumination profile is provided. The estimated illumination profile is mathematically represented as a weighted sum of polynomials. Furthermore, the estimated illumination profile has associated Zernike components based on the fitting in the third step 430.

The fitting in the third step 430 may be performed using a component of the measured data and simulated data other than the phase. For example, the measured data and simulated data may comprise the offset component. Beneficially, the offset component provides a good estimate of illumination profiles, but is relatively unaffected by aberrations. Furthermore, the offset component is approximately linear in illumination and apodization. Therefore, fitting the offset component can provide an accurate estimation of the illumination pupil and/or profile with relatively low processing requirements, because neither multiple components nor non-linear contributions need be taken into account. In an alternative implementation, the amplitude component may be used instead of, or as well as, the offset component. The amplitude component is only weakly dependent on aberrations but can provide a reliable means for estimating the illumination pupil and/or profile.

The method of determining an estimated illumination pupil and/or profile 400 can be performed alone, or can be performed as part of the method to determine an optical property of the projection system 300 as described above. The combination is particularly beneficial, because the fitting parameters generated during the profile fit when determining the estimated illumination pupil and/or profile can be used as a starting point for the parameter fit when determining the optical property.

An example implementation of the combination of both methods 300, 400 is as follows. Measurement data is obtained, in the form of an offset map (referred to as a measured offset map) and a phase map (referred to as a measured phase map) following providing input radiation to the projection system, measuring the output radiation in a phase stepping process, and extraction of offset and phase data therefrom. Simulated data is obtained, in the form of offset maps (referred to as simulated offset maps), by retrieving previously calculated simulated data from storage. The simulated data comprises multiple offset maps, each associated with one of the predetermined illumination profiles of the set of predetermined illumination profiles. Zernike polynomials are fitted to the (offset component of the) measured data, to calculate Zernike coefficients. The measured offset map can be fitted directly to the simulated offset maps. Alternatively, the maps can be compressed by representing each map in terms of Zernike polynomials. In the compressed format, the fitting can then be performed by comparison of the Zernike coefficients of the measured offset map and the Zernike coefficients of the simulated offset maps. Using the compressed format has the benefit that storage space is reduced and processing speed is increased.

The calculated Zernike coefficients are then used to determine a weighted combination of the simulated offset maps which, when fitted with Zernike polynomials, provides the same or similar Zernike coefficients. That is, the calculated Zernike coefficients are used to determine a weighted combination of the simulated offset maps which provide the best estimation of the measured offset map. The weights associated with the weighted combination of the simulated offset maps are then used to calculate a weighted combination of the associated predetermined illumination profiles. The calculated weighted combination of the predetermined illumination profiles therefore represents the estimated illumination profile.

Using the estimated illumination profile, estimated data is generated. The estimated data is in the form of a phase map (referred to as an estimated phase map). The estimated phase map is then fitted with Zernike polynomials to generate estimated Zernike coefficients. These estimated Zernike coefficients are used as a starting point to fit Zernike polynomials to the measured phase map to generate measured Zernike coefficients. Based on the measured Zernike coefficients, an optical property of the projection system, for example aberrations induced by the projection system, are determined.

Steps of the methods described herein may be combined. In such cases, one or more steps of a method (for example the method 300 of FIG. 3) may be combined with one or more steps of another method (for example the method 400 of FIG. 4) without requiring all steps to be used. That is, the method steps may be performed in isolation from other method steps. For example, in an alternative method which combines steps of the method 300 of FIG. 3 and the method 400 of FIG. 4, the process of determining an estimated illumination pupil and/or profile (for example in the fourth step 440 of the method 400 of FIG. 4) is removed.

In a first step, measured data is obtained as described with reference to FIGS. 2 and 3. In particular, the measured data may include a phase map.

In another step, simulated data is obtained. The simulated data represents simulated radiation that would be output from the projection system given a particular input radiation. The simulated data comprise multiple sets of simulated data. In this example implementation, each set is based upon the propagation of radiation through the projection system where the propagation system induces a particular aberration. For example, the aberration may be tilt, coma etc. or a combination thereof. The aberrations may be described using Zernike polynomials, for example with each aberration being represented by a different Zernike order. The simulated data can therefore include phase maps, where each phase map represents a simulated phase of radiation which has been affected by a particular aberration (e.g. of a particular Zernike order).

In another step, the measured data is fitted to the simulated data, for example as described with reference to the third step 430 of the method 400 of FIG. 4. The fitting can be performed by fitting the measured phase map to simulated phase maps. Alternatively, the maps can be compressed by representing each map in terms of Zernike polynomials. In the compressed format, the fitting can then be performed by comparison of the Zernike coefficients of the measured offset map and the Zernike coefficients of the simulated offset maps. Using the compressed format has the benefit that storage space is reduced and processing speed is increased.

In another step, step a phase map offset and a phase map dependency per Zernike are output. The phase map offset and phase map dependency may be generated based on the fit of the measured data to the simulated data. For example, they may represent a fit between the measured data and one of the set of simulated data. The therefore the phase map offset and phase map dependency can represent the fit of the measured data to a particular Zernike order, and therefore a particular aberration. In this way, fitting the measured data to the simulated data can be used to estimate the contribution of various aberrations induced by the projection system. The phase map dependency per Zernike represents the Jacobian of the phase map with respect to the Zernikes. The phase map dependency can show both linear and non-linear dependencies.

The performance of the methods described herein can be assessed as follows. A wavefront aberration map represents the distortions of the wavefront of light approaching a point in an image plane of the projection system from a spherical wavefront and can be expressed as a linear combination of Zernike polynomials:

$$W ( x , y ) = {\sum }_{n} {c}_{n} \cdot {Z}_{n} ( x , y ) \qquad ( 2 )$$

where x and y are coordinates in the pupil plane, Zₙ(x,y) is the n^{th} Zernike polynomial and cₙ is a coefficient, and n is the Noll index. It is possible to input a pure Zernike wavefront aberration map (for example Zₙ) into a reconstruction algorithm and to assess how the reconstruction algorithm reconstructs this as a linear combination of Zernike polynomials. Ideally, the reconstruction algorithm should output a set of Zernike coefficients cₘ such that cₘ=1 for m=n and cₘ=0 for m #n. Any variation of cₙ from 1 may be referred to as a gain error. Furthermore, any variation of cₘ from 0 where m≠n may be referred to as a cross-talk error.

In general, if a projection system has an aberration map that can be described by a vector of Zernike coefficients, c_{actual}, then a vector of Zernike coefficients, c_{reconstructed}, reconstructed by a reconstructions algorithm may be given by:

$${c}_{reconstructed} = M \cdot {c}_{actual} \qquad ( 3 )$$

where M is a matrix containing the gain errors and cross-talk errors of the reconstruction. In particular, the diagonal elements of the matrix M should ideally be 1 and the off-diagonal element are the cross-talk errors (and should ideally be zero). Therefore, ideally, matrix M should be the identity matrix, which would represent a perfect reconstruction. An error matrix E can be defined by:

$$E = M - I \qquad ( 4 )$$

where I is the identity matrix. The diagonal elements of the matrix E are the gain errors (and should ideally be zero) and the off-diagonal element are the cross-talk errors (and should ideally be zero). Matrix E therefore represents a good figure of merit for assessing the errors in the aberration map reconstruction.

An error matrix E associated with another method of determining optical properties of the projection system, which does not use estimated data, can exhibit error magnitudes in a range greater than −250 to 200. On the other hand, the error matrix associated with the method described herein has significantly lower errors, with the error magnitude generally in the range −10 to 40, demonstrating the improved performance of the methods described herein using estimated data. Cross-talk errors are also improved when using estimated data as described herein.

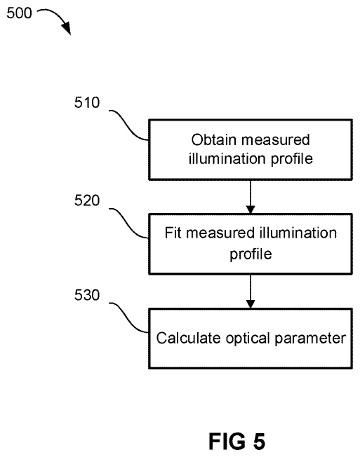

FIG. 5 illustrates an alternative method 500 for determining an optical property of the projection system. In a first step 510, a measured illumination profile is determined. The measured illumination profile is associated with an illumination profile of radiation output from the projection system. The measured illumination profile may comprise information about, for example, an illumination pupil, polarization and/or apodization.

The measured illumination profile may be measured using a variation upon the measurement system depicted in FIG. 2. In the variation, rather than providing the first and second measurement patterning devices MA′, MA″, a pinhole is provided in place of the first measurement patterning device MA′. The pinhole is illuminated such that an image of the pinhole (or an interference pattern from the pinhole) is formed at the sensor 26. The positioning system PW scans the pinhole and the sensor 26 relative to one another and measures the radiation received at the sensor at each scanning location. A measured illumination profile can then be extracted from the signal output from the sensor 26 using known methods.

In a second step 520, the measured illumination profile is fitted to a set of predetermined illumination profiles. The set of predetermined illumination profiles may be the same set of predetermined illumination profiles described above with reference to FIG. 4. The fitting may be performed in the same manner as also described above, for example using Zernike basis functions. The fit may provide a parameter fit, for example in the form of Zernike coefficients.

In a third step 530, the optical property of the projection system is calculated. The optical property may be determined directly from the parameter fit determined in the previous step. Alternatively, measured data may also be obtained (using any of the methods described above) and fitted using the parameter fit as a starting point. The fit of the measured data may subsequently be used to calculate the optical property.

The generation of measured data described herein may be performed offline, that is not during the determination of the optical properties or estimated illumination profile methods. As such, the measurement system 20 need not comprise the sensor, measurement patterning devices or positioning system in order to perform the methods for determining an optical property described herein. Rather, the measured data may be obtained, for example by retrieval from a storage device, rather than being generated on-demand. Furthermore, the measurement system 20, while pictured as comprising a controller for applying an adjustment to the projection system PS or other component, the methods for determining an optical property may be performed without the need for a controller.

The data described herein may be in the form of images or in any other data format, for example a matrix, tensor or other structured data format. While examples given herein illustrate the specific use of certain components, for example offset or phase, the methods may alternatively or additionally use other components. For example, the measured data, simulated data and/or estimated data may each comprise one or more of offset, phase and amplitude data.

The fitting described herein can be performed using images, for example by fitting measured camera images to simulated camera images. Alternatively, a compressed fitting method may be used. A compressed method includes determining a simplified Zernike fit to data, for example to a phase map, and storing the data in a compressed data form, for example in the form of Zernike coefficients. When a subsequent fit is required, the entire measured data set need not be fitted to, for example, the estimated data. Rather, the compressed data is fitted to the estimated data. A compressed method such as this could reduce the required storage space and increase calculation speed.

Where a fitting is performed for the purposes of determining an optical property of the projection system, the output of the fitting may be referred to as a parameter fit. Where a fitting is performed for the purposes of determining an illumination profile, the output of the fitting may be referred to as a profile fit. The output of a fitting may be, for example, a set of Zernike coefficients.

Although specific reference may be made in this text to embodiments of the invention in the context of a lithographic apparatus, the methods and apparatus described herein may be used in other systems. The methods and apparatus described herein may be used in combination with a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Where the context allows, the methods and systems described herein may be implemented in hardware, firmware, software, or any combination thereof. The methods may be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses
1. A method for determining an optical property of a projection system, the method comprising:
   obtaining measured data representative of measured radiation output from the projection system;
   obtaining an estimated illumination profile of input radiation received by the projection system;
   generating, based on the estimated illumination profile, estimated data representative of estimated radiation output from the projection system;
   fitting the estimated data to the measured data to generate a parameter fit; and
   calculating, based on the parameter fit, an optical property of the projection system.
2. The method of clause 1, wherein the measured data represents at least one component of the measured output radiation, wherein the component is selected from the set of: a phase component, an amplitude component, and an offset component; and the estimated data represents a corresponding at least one component of the estimated output radiation.
3. The method of clause 1 or 2, wherein the component of the measured data and the corresponding component of the estimated data each comprise the phase component.
4. The method of any preceding clause, wherein obtaining the estimated illumination profile comprises:
   obtaining simulated data representative of simulated radiation output from the projection system, wherein the simulated data comprises multiple sets of simulated data and each set of the multiple sets is based on the input, to the projection system, of radiation with a predetermined illumination profile of a set of predetermined illumination profiles; and
   fitting the measured data to the simulated data to generate a profile fit;
   generating, based on the profile fit, the estimated illumination profile, wherein the estimated illumination profile comprises a weighted combination of the set of predetermined illumination profiles.
5. The method of clause 4, wherein each of the predetermined illumination profiles is at least partially defined by an angular distribution, an apodization and/or a polarization of the input radiation.
6. The method of clause 4 or 5, wherein:
   the measured data represents at least one component of the measured output radiation, the at least one component being selected from the set of: a phase component, an amplitude component, and an offset component; and
   the simulated data represents a corresponding at least one component of the estimated output radiation.
7. The method of clause 6, wherein the component of the measured data and the corresponding component of the simulated data each comprise the offset component.
8. The method of any preceding clause, wherein the measured data, the simulated data and/or the estimated data comprise images.
9. The method of any of clauses 4 to 8, wherein the simulated data is calculated by obtaining a theoretical model of the projection system and propagating each of the set of predetermined illumination profiles using said theoretical model.
10. The method of any preceding clause, wherein fitting comprises fitting basis functions to the data.
11. The method of clause 10, wherein the basis functions are Zernike polynomials.
12. The method of any preceding clause, wherein the optical property comprises one or more aberrations induced by the projection system.
13. The method of any of clauses 4 to 12, wherein each of the predetermined illumination profiles are represented using polynomials.
14. The method of any preceding clause, further comprising calculating an adjustment based on the determined optical property.
15. The method of clause 14, wherein the adjustment comprises a calibration of the projection system or a component external to the projection system.
16. The method of clause 14 or 15, wherein the adjustment comprises or further comprises a real-time control operation.
17. The method of any of clauses 14 to 16, further comprising providing an instruction to a means for adjusting the projection system or external component to apply said adjustment.
18. The method of any preceding clause, further comprising providing an indication that the projection system or an element thereof needs replacing or cleaning.
19. A method for determining an optical property of a projection system, the method comprising:
   obtaining a measured illumination profile of input radiation received by the projection system;
   fitting the measured illumination profile to a set of predetermined illumination profiles to generate a parameter fit; and
   calculating, based on the parameter fit, an optical property of the projection system.
20. The method of clause 19, wherein obtaining a measured illumination profile comprises: illuminating a pinhole in an object plane of the projection system and receiving radiation output from the projection system while scanning said illuminated pinhole within the object plane.
21. The method of clause 19 or 20, wherein each of the predetermined illumination profiles is at least partially defined by an intensity, an apodization and/or a polarization of the input radiation.
22. A method of determining an estimated illumination profile of a projection system, comprising:
   obtaining measured data representative of measured radiation output from the projection system;
   obtaining simulated data representative of simulated radiation output from the projection system, wherein the simulated data comprises multiple sets of simulated data and each set of the multiple sets is based on the input, to the projection system, of radiation with a predetermined illumination profile of a set of predetermined illumination profiles;
   fitting the measured data to the simulated data to generate a profile fit; and
   generating, based on the profile fit, the estimated illumination profile, wherein the estimated illumination profile comprises a weighted combination of the set of predetermined illumination profiles.
23. A method for determining an optical property of a projection system, the method comprising:
   obtaining measured data representative of measured radiation output from the projection system;
   obtaining simulated data representative of simulated radiation output from the projection system, wherein the simulated data comprises multiple sets of simulated data and each set of the multiple sets of simulated data is based on an aberration of a set of known aberrations; and
   fitting the measured data to the simulated data to generate a parameter fit;
   calculating, based on the parameter fit, an optical property of the projection system.
24. A computer-readable medium comprising instructions which, when executed by a computer, cause the computer to perform the method of any preceding clause.
25. A measurement system comprising a projection system and a processor configured to perform the method of any of clauses 1 to 23.
26. The measurement system of clause 25, further comprising:
   a first support configured to hold a first measurement patterning device in an object plane of the projection system;
   a second support configured to hold a second measurement patterning device in an image plane of the projection system;
   a positioning system configured to scan at least one of the first and second supports with respect to the other of the first and second supports; and
   a sensor configured to generate the measured data.
27. The measurement system of clause 25 or 26, further comprising a controller operable to
   apply an adjustment to the projection system or a component external to the projection system; and/or
   provide an indication that the projection system or an element thereof needs replacing or cleaning.
28. A lithographic apparatus comprising the measurement system of any of clauses 25 to 27.
29. The lithographic apparatus of clause 28, further comprising a controller operable to apply an adjustment to the lithographic apparatus.
30. The lithographic apparatus of clause 28 or 29, further comprising a display screen configured to display an indication.

1. A method for determining an optical property of a projection system, the method comprising:
obtaining measured data representative of measured radiation output from the projection system;
obtaining an estimated illumination profile of input radiation received by the projection system;
generating, by a hardware computer system and based on the estimated illumination profile, estimated data representative of estimated radiation output from the projection system;
fitting the estimated data to the measured data to generate a parameter fit; and
determining, based on the parameter fit, the optical property of the projection system.

2. The method of claim 1, wherein the measured data represents at least one component of the measured output radiation, wherein the component is selected from the set of: a phase component, an amplitude component, and an offset component; and the estimated data represents a corresponding at least one component of the estimated output radiation.

3. The method of claim 1, wherein the component of the measured data and the corresponding component of the estimated data each comprise a phase component.

4. The method of claim 1, wherein obtaining the estimated illumination profile comprises:
obtaining simulated data representative of simulated radiation output from the projection system, wherein the simulated data comprises multiple sets of simulated data and each set of the multiple sets is based on the input, to the projection system, of radiation with a predetermined illumination profile of a set of predetermined illumination profiles; and
fitting the measured data to the simulated data to generate a profile fit;
generating, based on the profile fit, the estimated illumination profile, wherein the estimated illumination profile comprises a weighted combination of the set of predetermined illumination profiles.

5. The method of claim 1, wherein the measured data, the simulated data and/or the estimated data comprise images.

6. The method of claim 1, wherein fitting comprises fitting basis functions to the data.

7. The method of claim 1, wherein the optical property comprises one or more aberrations induced by the projection system.

8. The method of claim 1, further comprising determining an adjustment based on the determined optical property.

9. The method of claim 1, further comprising providing an indication that the projection system or an element thereof needs replacing or cleaning.

10. A method for determining an optical property of a projection system, the method comprising:
obtaining a measured illumination profile of input radiation received by the projection system;
fitting, by a hardware computer system, the measured illumination profile to a set of predetermined illumination profiles to generate a parameter fit; and
determining, based on the parameter fit, the optical property of the projection system.

11. A method of determining an estimated illumination profile of a projection system, the method comprising:
obtaining measured data representative of measured radiation output from the projection system;
obtaining simulated data representative of simulated radiation output from the projection system, wherein the simulated data comprises multiple sets of simulated data and each set of the multiple sets is based on the input, to the projection system, of radiation with a predetermined illumination profile of a set of predetermined illumination profiles;
fitting the measured data to the simulated data to generate a profile fit; and
generating, by a hardware computer system and based on the profile fit, the estimated illumination profile, wherein the estimated illumination profile comprises a weighted combination of the set of predetermined illumination profiles.

12. A method for determining an optical property of a projection system, the method comprising:
obtaining measured data representative of measured radiation output from the projection system;
obtaining simulated data representative of simulated radiation output from the projection system, wherein the simulated data comprises multiple sets of simulated data and each set of the multiple sets of simulated data is based on an aberration of a set of known aberrations;
fitting the measured data to the simulated data to generate a parameter fit; and
determining, by a hardware computer system and based on the parameter fit, the optical property of the projection system.

13. A computer-readable medium comprising instructions which, when executed by a computer system, are configured to cause the computer system to perform at least the method of claim 1.

14. A measurement system comprising a projection system and a processor configured to perform the method of claim 1.

15. A lithographic apparatus comprising the measurement system of claim 14.

16. The method of claim 10, wherein the optical property comprises one or more aberrations induced by the projection system.

17. A computer-readable medium comprising instructions which, when executed by a computer system, are configured to cause the computer system to perform at least the method of claim 10.

18. A computer-readable medium comprising instructions which, when executed by a computer system, are configured to cause the computer system to perform at least the method of claim 11.

19. The method of claim 12, wherein the optical property comprises one or more aberrations induced by the projection system.

20. A computer-readable medium comprising instructions which, when executed by a computer system, are configured to cause the computer system to perform at least the method of claim 12.
